(19) United States
(12) Patent Application Publication
(10) Pub. No.: US 2002/0072224 A1
(43) Pub. Date: Jun. 13, 2002

(54) Method for improving local interconnects of multi-level interconnects process

(75) Inventors: Jui-Tsen Huang, Taipei City (TW); Michael Wc Huang, Hsin-Tien City (TW)

Correspondence Address: Benjamin J. Hauptman, LOWE HAUPTMAN GILMAN & BERNER, Suite 310, 1700 Diagonal Road, Alexandria, VA, 22314, US

(73) Assignee: United Microelectronics Corp.

(21) Appl. No.: 09/731,018

(22) Filed: Dec. 7, 2000

(51) Int. Cl. H01L 21/3205; H01L 21/4763

(52) U.S. Cl. 438/631

(57) ABSTRACT

A method for forming local interconnect of multi-level interconnects process. The method at least includes the following steps. First of all, a silicon substrate is provided with a MOS transistor and shallow isolation region formed therein and thereon, wherein the MOS transistor comprises gate and source/drain, and a silicon oxide layer is deposited on the structure. Then, silicon oxide layer is patterned to etch that to define a trench line and contact hole, immediately a silicon nitride layer is deposited to filled up the trench line, and bottom and sidewall of the contact hole. The silicon nitride layer is etched in the contact hole to form a silicon nitride spacer, and the silicon oxide layer is removed under the contact hole to form a contact window. Next, the silicon nitride trench line and the silicon nitride spacer is removed to form a local interconnect contact window. Final, a metal layer is deposited into local interconnect contact window to form a local interconnect metal layer, and the local interconnect metal layer is planarized.

### BACKGROUND OF THE INVENTION

1. Field of the Invention

The present invention generally relates to a method for improving fabrication of local interconnects of multi-level interconnects, and more particularly to a method for reducing critical dimension of local interconnects to solve junction leaking or high sheet resistance cased by inappropriate etching in formation of interconnect contact window.

2. Description of the Prior Art

Along the development tendency of semiconductor integrated circuits, area of a semiconductor device shrinks more and more. However, the shrink of gate length in a transistor can promote speed of processor or DRAM, and improve function of a device. Nevertheless, RC delay of conductor will increase harmfully. In pre-micron era, transmission duration of gate excessively exceeds delay duration in conductor connector. When VLSI of million bits is developed, delay duration in conductor connector of sub micron device is close to transmission duration of gate. Therefor, it is a necessary method to utilize multi-level interconnects to reduce length of connector and to reduce resistance. In earlier period of integrated circuits, vertical and horizontal connector are formed at one step. It can be completed easily especially when width of connector is excessively large than thickness of metal film. However, it is difficult to fabricate in micron width, and a complete different technology needs to be developed.

Moreover, when more and more circuits are integrated, surface of a chip cannot provide enough area to fabricate interconnects. In order to comply with requirement of increased connector in reduced MOS transistor, design with at least two metal levels is a suitable adapted method in integrated circuits. More particularly, function with more complex product, such as microprocessor, even needs four to five metal levels to fabricate connection among each device in microprocessor.

FIG. 1 shows conventional method for forming local interconnects in metal layer structure. A silicon substrate 10 is provided with a MOS transistor and shallow isolation region 12 formed therein and thereon, wherein the MOS transistor comprises gate 16, source/drain 14, spacer 18 and cobalt salicide layer 20. After the formation of the transistor, a conventional etching step is performed to form local interconnect contact window. Then, a metal layer is deposited into this local interconnect contact window to form local interconnect metal layer 22.

Essentially, formation of local interconnect would shrink in a chip area, and promote device operation speed. However, all line width of local interconnect and area of contact hole are fixed in conventional circuit design rule, and do not adjust suitable with increased integrated circuits in a chip. Hence, it is all most impossible that etching process will stop on the cobalt salicide layer of gate, silicon oxide of trench isolation and cobalt salicide layer on source/drain, and not cause any cobalt salicide consumption in the formation of local interconnect contact window by using etching process.

In cobalt salicide on the gate consumed too much in etching process, it will cause high sheet resistance on gate, and operation seed is therefor reduced. Moreover, if silicon oxide in shallow trench isolation region consumes too much in etching problems, it will cause leaking issue. According to the above-described problem, a more suitable method for forming local interconnect metal layer for semiconductor development is necessary.

### SUMMARY OF THE INVENTION

In accordance with the present invention the main object of the invention is to reduce critical dimension of local interconnect by changing layout to form more reliable and large area local interconnect and to improve alignment in lithography.

It is another object of the invention to prevent form excessively consuming cobalt salicide layer of gate and source/drain that causes high sheet resistance.

It is a further object of this invention to prevent form excessively silicon oxide of shallow trench isolation region that causes leaking issue.

In order to achieve the above objects of this invention, the present invention provides a method for forming local interconnect of multi-level interconnects process. The method at least includes the following steps. First of all, a silicon substrate is provided with a MOS transistor and shallow isolation region formed therein and thereon, wherein the MOS transistor comprises gate and source/drain, and a silicon oxide layer is deposited on the structure. Then, silicon oxide layer is patterned to etch that to define a trench line and contact hole, immediately a silicon nitride layer is deposited to filled up the trench line, and bottom and sidewall of the contact hole. The silicon nitride layer is etched in the contact hole to form a silicon nitride spacer, and the silicon oxide layer is removed under the contact hole to form a contact window. Next, the silicon nitride trench line and the silicon nitride spacer is removed to form a local interconnect contact window. Final, a metal layer is deposited into local interconnect contact window to form a local interconnect metal layer, and the local interconnect metal layer is planarized.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1 is cross-sectional view of local interconnect of multilevel interconnects in accordance with conventional;

FIG. 2A to FIG. 2H are cross-sectional views of structures at various stages during the formulation of local interconnect of multilevel interconnects in accordance with the method of this disclosure.

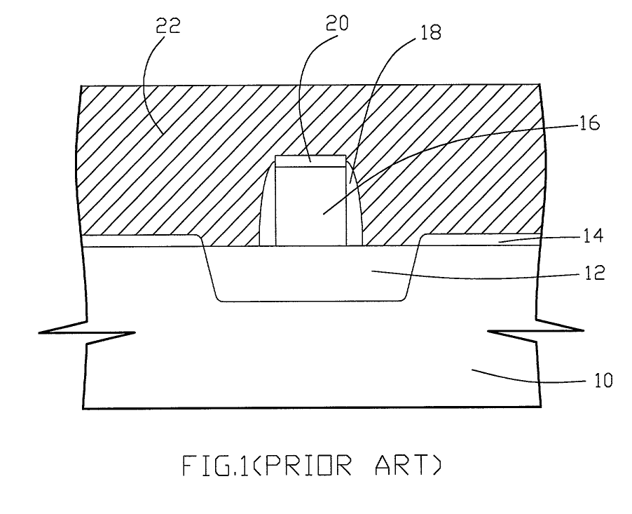

### DESCRIPTION OF THE PREFERRED EMBODIMENT

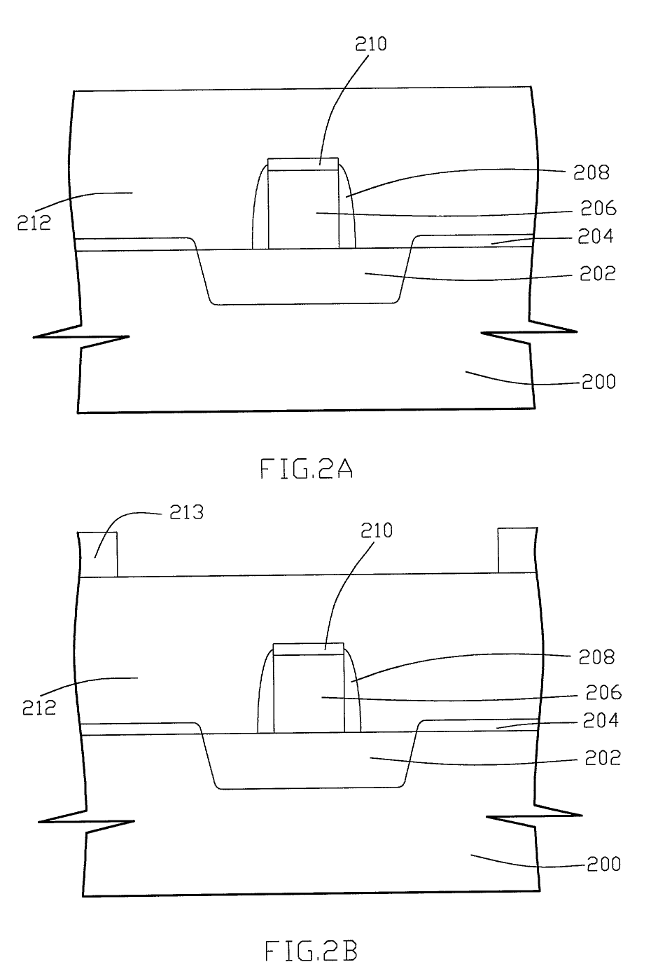

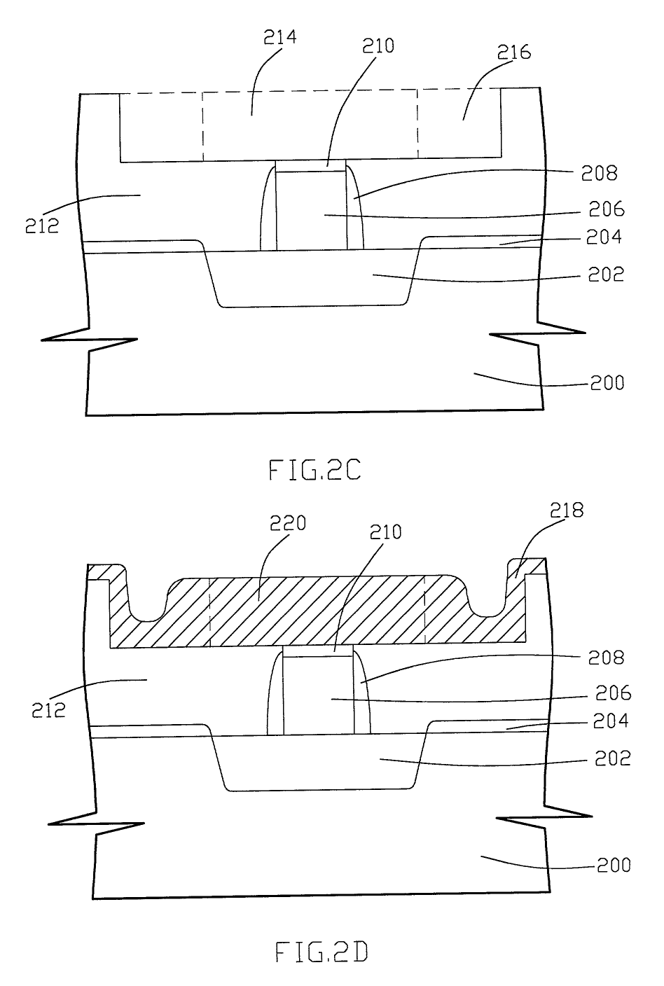

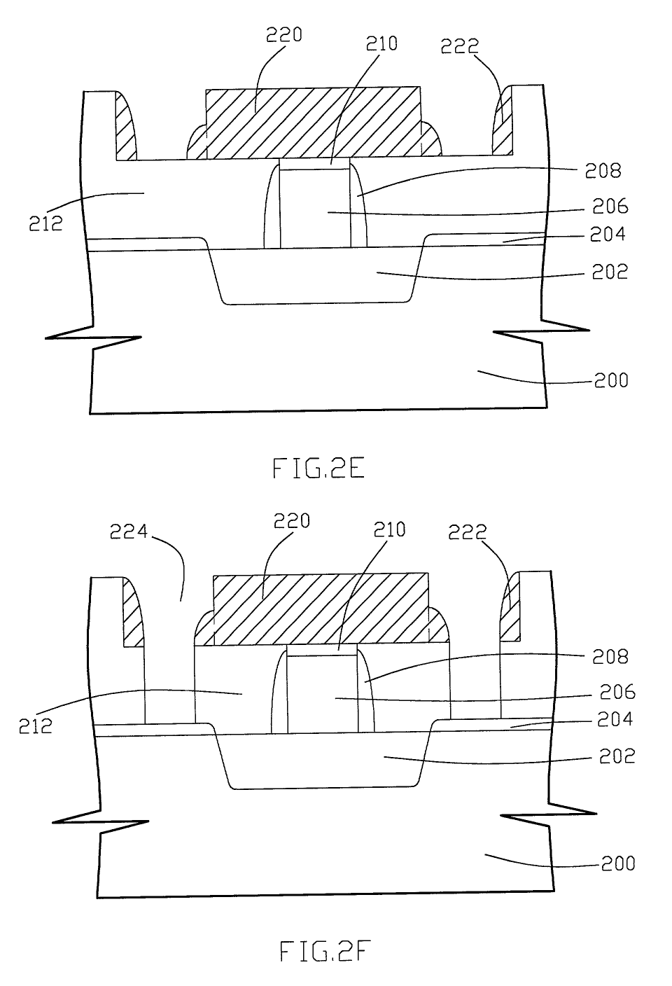

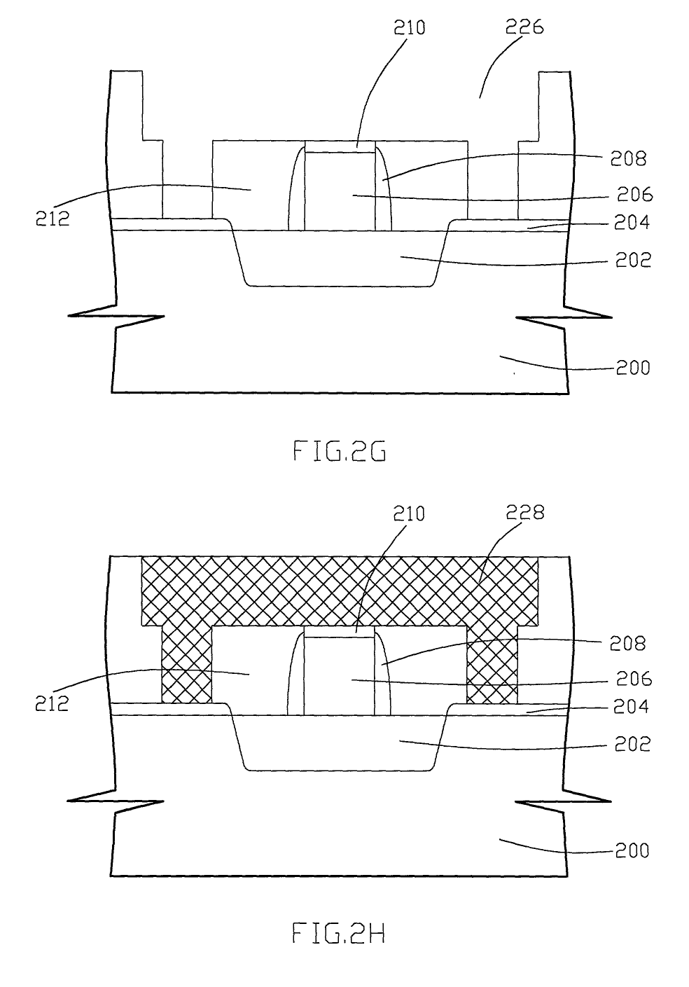

FIG. 2A to FIG. 2H show schematic representations of structures at various stages during the formulation of local interconnect of multilevel interconnects in accordance with the method of this disclosure.

Referring to FIG. 2A, a silicon substrate 200 with a MOS transistor and trench isolation structure 202 are formed therein and thereon ' wherein the MOS transistor includes gate 206, CoSix layer 204 on the top of source/drain, spacer 208 and cobalt salicide layer 210 on the top of the gate 206. More particularly, it needs to be meatiness that CoSix layer 204 on the top of source/drain belongs to a different MOS transistor. A silicon oxide layer 212, which is TEOS in a thickness between about 4000˜5000 angstroms, is formed on the substrate 200 within MOS transistor by using LPCVD method, as shown in FIG. 2A. Then, a patterned photoresist layer 213 is formed on the silicon oxide layer 212, as shown in FIG. 2B. The silicon oxide layer 212 is then etched by using the photoresist layer 213 as a mask, and this etch step will stop on the cobalt salicide layer 210 on top of the gate 206 to define local interconnect. The photoresist layer 213 is then stripped. The local interconnects include trench line region 214 and contract hole 216, and width of the trench line 214 is about equal to width of the shallow trench isolation region 202. Then contract hole 216 is located on flank of trench line, as shown in FIG. 2C.

A silicate nitride is then deposited in trench line 214 and contract hole 216 by using LPCVD method. The depositing condition is adjusted such that trench line region 214 will be filled up to from silicon nitride trench line 220, while only bottom and sidewall of contact hole 216, not all contact hole 216, are filled by silicon nitride to form local silicon nitride contact hole 218, as shown in FIG. 2D. Then, an anisotropical etching is performed to the local silicon nitride contact hole 218 to form silicon nitride spacer 22 in contact hole 216, as shown in FIG. 2E.

Moreover, silicon oxide layer 212 under the contact hole 216 with silicon nitride spacer 222 is removed to form contact window 224, as shown in FIG. 2F. Critical dimension of contact window 216 can be changed to prevent form overetching and consuming silicon oxide in shallow trench isolation region 200, And further to prevent form junction leaking issue by using protection of silicon nitride spacer 222.

Then, the silicon nitride trench line 220 and silicon nitride spacer 222 are remove to form local interconnect contact window 226, as shown in FIG. 2G. A barrier layer, usually titanium nitride, is deposited local interconnect contact window 226 and a metal layer 228 is capped into this local interconnect contact window 226, by using sputtering method. A CMP method is usually utilized to planarize surface of the local interconnect metal layer 228, as shown in FIG. 2H.

Although one specific embodiment have been illustrated and described, it will be obvious to those skilled in the art that various modifications may be made without departing from what is intended to be limited solely by the appended claims.

What is claimed is:

1. A method for forming local interconnect, said method comprising:
providing a substrate having a MOS transistor, a trench isolation region;
blanket depositing an insulator layer on said structure;
patterning to etch said insulator layer to define a local interconnect, wherein said local interconnect includes a trench line and a contact hole;
depositing a dielectric layer in said local interconnect;
etching said dielectric layer in said contact hole to form a spacer;
removing said insulator layer by using the spacer as a mask to form a contact window under said contact hole;
removing said dielectric layer and said spacer to form a local interconnect contact window;
blanket depositing a metal layer into said local interconnect contact window to form a local interconnect metal layer; and
planarizing said local interconnect metal layer.

2. The method according to claim 1, wherein said substrate comprises silicon.

3. The method according to claim 1, wherein said MOS transistor comprises a gate, and a soure/drain.

4. The method according to claim 1, wherein said gate further comprises a gate spacer and a cobalt salicide layer on top of said gate.

5. The method according to claim 1, wherein said insulator layer is silicon oxide.

6. The method according to claim 1, wherein width of said trench line is about equal to width of said shallow trench isolation region.

7. The method according to claim 6, wherein said contact hole is located on flank of said trench line.

8. The method according to claim 4, wherein said local interconnect etching is formed and defined by etching layer to stop on said cobalt salicide layer of said gate.

9. The method according to claim 1, wherein said dielectric layer is silicon nitride.

10. The method according to claim 1, wherein said dielectric layer fills up said trench line, and bottom and sidewall of said contact hole.

11. The method according to claim 1, wherein the step of depositing said metal layer is sputtering method.

12. The method according to claim 11, wherein said metal layer is cobalt salicide.

13. The method according to claim 11, wherein said metal layer is titanium salicide.

14. The method according to claim 1, wherein said local interconnect metal layer is planarized by the CMP method.

15. A method for forming local interconnect of multi-level Interconnects process, said method comprising:
providing a substrate having a MOS transistor, a trench isolation region, a spacer and a source/drain;
blanket depositing a silicon oxide layer on said structure;
forming a photoresist layer having an etch pattern on the silicon oxide layer, and then etching stop on top of said gate to define a local interconnect, wherein said local interconnect includes a trench line and a contact hole;
depositing a silicon nitride layer to fill up said trench line, and bottom and sidewall of said contact hole;
etching said silicon nitride layer in said contact hole to form a silicon nitride spacer;
removing said silicon oxide layer under the contact hole with silicon nitride spacer to form a contact window;
removing said silicon nitride trench line and said silicon nitride spacer to form a local interconnect contact window;
blanket depositing a metal layer into local interconnect contact window to form a local interconnect metal layer; and
planarizing said local interconnect metal layer.

16. The method according to claim 15, wherein said substrate comprises silicon.

17. The method according to claim 15, wherein said gate comprises a gate spacer, and a cobalt salicide.

18. The method according to claim 17, wherein on top of said gate is a cobalt salicide layer.

19. The method according to claim 15, wherein the step of depositing said metal layer is sputtering method.

20. The method according to claim 19, wherein the step of depositing said metal layer is sputtering method.

21. The method according to claim 19, wherein said metal layer is titanium salicide.

22. The method according to claim 15, wherein said local interconnect metal layer is planarized by the CMP method.

23. The method according to claim 15, wherein width of said trench line is about equal to width of said shallow trench isolation region.

24. The method according to claim 15, wherein said contact hole is located on flank of said trench line.
